(19) United States
(12) Patent Application Publication
(10) Pub. No.: US 2007/0205667 A1
(43) Pub. Date: Sep. 6, 2007

(54) Serial ATA cable with light display feature

(76) Inventors: Peng-Fei Lin, Hsinchu City (TW); Ming-Hung Wang, Hsinchu City (TW)

Correspondence Address: LIN & ASSOCIATES INTELLECTUAL PROPERTY, P.O. BOX 2339, SARATOGA, CA, 95070-0339, US

(21) Appl. No.: 11/367,897

(22) Filed: Mar. 3, 2006

(51) Int. Cl. H05K 1/02

(52) U.S. Cl. 307/42

(57) ABSTRACT

The present invention provides a SATA cable with light display feature, which is mainly used for the SATA cables for computer host and their peripheral devices. With the light display capability, the connection readiness status and the signal transmission conditions can be easily detected via the pins on the SATA cable. The realization technique used by the present invention is adding the LED lights and the control pins inlayed at the two plug-in ends of the SATA cable. When the two plug-in ends of the SATA cable are both connected and ready, or there is data transmission going on, the control pins automatically turn on the LED lights to indicate the ON/ACTIVE connection status/condition.

### FIELD OF THE INVENTION

The present invention generally relates to a SATA cable, and more specifically to a SATA cable with light display feature.

### BACKGROUND OF THE INVENTION

Since the emergence of IBM's PC/AT, PC or laptop computer has become ubiquitous. The AT attachment (ATA) or the ATA packet interface (ATAPI) between AT and devices has become the most popular device interface. For example, more than 90% of the hard disks use ATA interface, and the remaining uses SCSI interface. In addition, the majority of CD-ROM uses ATAPI, and the majority of PCMCIA and CFA mass storage devices also use ATA or ATAPI interface.

Serial ATA (SATA) is the newest version of the ATA interface. SATA can support the conventional parallel ATA interface for the internal disk drives inside the PC or laptop computer. In additionally, the Serial ATA interface is well suited for external applications with its simple connector and hot-plug feature. The SATA cables, which connect the host and its peripherals, are lacking of a capability/feature to visibly distinguish the status of the connection. For example, with a connection status light attached to a SATA cable, it would be easier to verify/confirm the readiness of the communication when the SATA cables are physically connected.

### SUMMARY OF THE INVENTION

The primary objective of the present invention is to provide an enhanced SATA cable with light display feature, such that when the two plug-in ends of the SATA cable are connecting the host and a peripheral device, the light display capability of the plug-in ends facilitates users with an obvious status indicator for the connectivity status of the SATA cable.

Another objective of the present invention is to provide an enhanced SATA cable with light display feature, such that the feature is activated as long as the SATA cable is connected to a computer socket. Driven by the power from the computer plug-in sockets, the enhanced SATA cable does not need extra battery or external power supply for the new light display feature, and provides great advantages of usage convenience.

Alternatively, the light display feature of an enhanced SATA cable according to the present invention can be designed in varieties in terms of the color as well as the light emitting pattern of the emitting light. For examples, there can be SATA cables with red display lights; or with flashing display light, or with any other light display patterns, etc.

With the aforementioned basic principle, the major technology of the present invention is to inlay light emitting diode (LED) lights on the plug-in ends of a SATA cable and add the LED control circuits within the plug-in ends to control the display of the LED light. When the two plug-in ends of a SATA cable are connected to the sockets of the host and peripheral devices, the LED control circuits in the plug-in ends are triggered to turn on the inlayed LED lights to display and indicate the readiness status for the SATA cable connectivity.

Additionally, the inlayed display lights on the SATA cables according to the present invention can show the actual pattern of the data transmission within the SATA cables. From computer manufactures' marketing perspective, this light display add-on of the SATA cables is considered a very attractive feature for the young computer nerds who are constantly after exciting and stylish varieties.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows a structural view of a first embodiment according to the present invention.

FIG. 2 shows a structural view of a second embodiment according to the present invention.

### DETAILED DESCRIPTION OF THE PREFERRED EMBODIMENTS

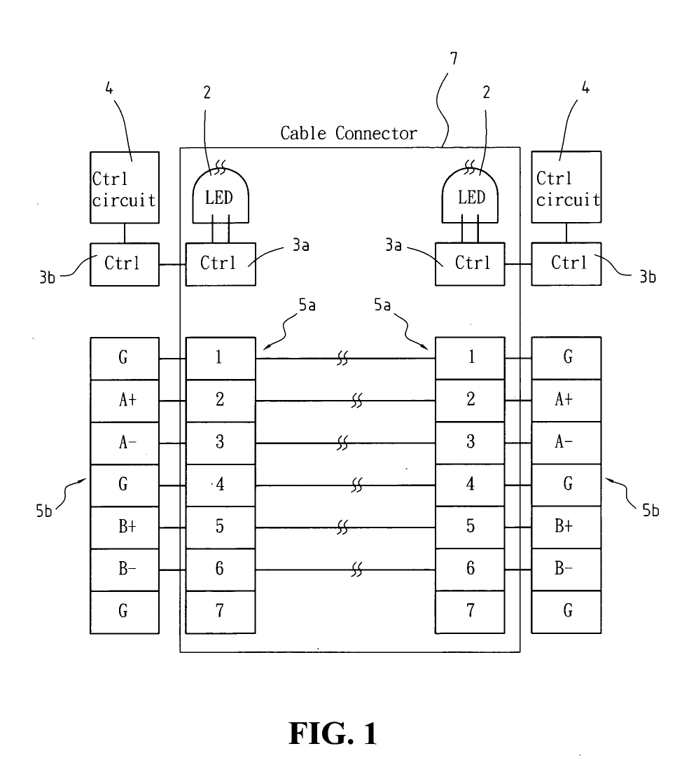

FIG. 1 shows a structural view of a first embodiment of the SATA cable with light display feature according to the present invention. The technology used in the present invention is to inlay an LED light 2 and an LED control pin 3a in the two plug-in ends of the SATA cable 7. The control pin 3a connects the LED light 2 and provides the power to control the lighting of the LED 2. When the two ends of the SATA cable 7 connect to the transmission port of a computer or a peripheral device, after the communication protocol between the physical layers is confirmed in link and the communication amongst the Serial ATA elements is established, the control circuit 4 in the physical layer receives the instructional signal from inside of the physical layer, then transmits the control signal through the control pin 3b on the receptacle of the SATA elements, to the control pin 3a of the SATA cable 7 to trigger the display of the LED light 2. Simultaneously, with the communication protocol between communications lines, the control circuit 4 is triggered to control the signals to vary the display pattern of the LED light 2. There is no need for the control circuit 4 to have the detecting function if the SATA cable 7 is connected with the host or the peripheral device. The communication protocol between the PHY (physical layer) for the host end and the peripheral device end has been confirmed by the data transmission via the pins A+, A−, B+, and B−, to assure the data communication readiness between the host and the device. Once the communication readiness amongst the SATA elements is verified and in confirmed state, the control signals transformed between the physical layers (PHY) trigger the control circuit of the LED light into the display mode.

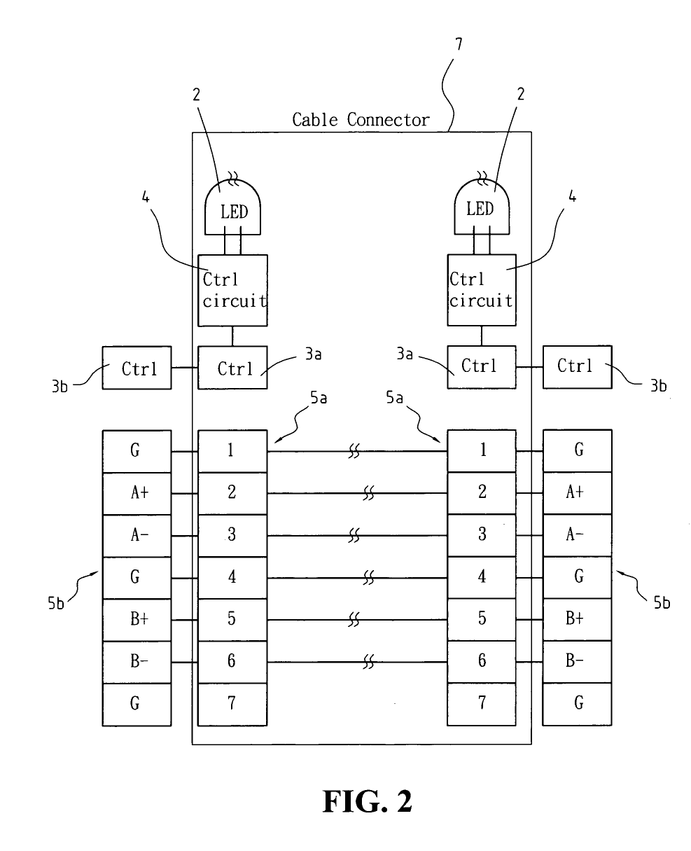

FIG. 2 shows a structural view of another embodiment of a SATA cable with light display feature according to the present invention. The only difference from the first embodiment shown in FIG. 1 is that the control circuit 4 is inlayed within the SATA cable 7. The physical layer communication of the SATA cable 7 is accomplished by transforming the control signals via pin 3a to drive the LED light 2 inlayed within the SATA cable 7 to emit light signals.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A SATA cable with light display feature, comprising:
a SATA cable;
one or more light sources installed on said SATA cable;
a plurality of transmission pins installed at said two plug-in ends of said SATA cable;
a control pin, installed at two plug-in ends of said SATA cable, and transmitting electrical signals to said light sources, when said SATA cable connects to a transmission socket, said transmission pin detects the said electrical signals transmitted, and said control pin transmits electrical signal to turn on said light sources.

2. The SATA cable with light display feature as claimed in claim 1, wherein said SATA cable contains control circuits to control the display function of said light sources.

3. The SATA cable with light display feature as claimed in claim 1, wherein said light emitter starts emitting light while data is transmitting in said SATA cable.

4. The SATA cable with light display feature as claimed in claim 3, wherein said light display pattern of said light sources is continuously lighting.

5. The SATA cable with light display feature as claimed in claim 3, wherein said light display pattern of said light sources is flashing.

6. The SATA cable with light display feature as claimed in claim 1, wherein said light sources is inlayed in said two plug-in ends of said SATA cable.

7. The SATA cable with light display feature as claimed in claim 1, wherein said light source is an LED light.

8. The SATA cable with light display feature as claimed in claim 1, wherein said light sources are colored.
